(19) United States
(12) Patent Application Publication
(10) Pub. No.: US 2026/0243486 A1
(43) Pub. Date: Aug. 20, 2026

(54) COOLING DEVICE, EXPOSURE DEVICE, AND INDUSTRIAL EQUIPMENT

(71) Applicant: CANON SEMICONDUCTOR EQUIPMENT INC., Ibaraki (JP)

(72) Inventors: Yuusuke SUZUKI, Ibaraki (JP); Masato SEIMIYA, Ibaraki (JP)

(21) Appl. No.: 19/642,971

(22) Filed: Apr. 9, 2026

Related U.S. Application Data
(63) Continuation of application No. PCT/JP2024/034392, filed on Sep. 26, 2024.

(30) Foreign Application Priority Data
Oct. 20, 2023 (JP) 2023-181052

(51) Int. Cl. F25B 49/02; F25B 5/02

(52) U.S. Cl. CPC F25B 49/022; F25B 5/02; F25B 2600/0253; F25B 2600/2513; F25B 2700/197; F25B 2700/21175

(57) ABSTRACT

A cooling device includes a first refrigeration cycle, a second refrigeration cycle, and a control unit. The control unit is configured to: control driving of the compressor based on a temperature of the second cooling target, acquire a first degree of superheat from a temperature and/or a pressure of the refrigerant at a position downstream of the first evaporator, and control an opening/closing degree of the first decompressor based on the first degree of superheat, acquire a second degree of superheat of the refrigerant, from a temperature and/or a pressure of the refrigerant at a position downstream of the second evaporator, and control an opening/closing degree of the second decompressor based on the second degree of superheat, and control an opening/closing degree of the evaporation pressure regulating valve based on a target pressure of the refrigerant or a temperature of the first cooling target.

### CROSS-REFERENCE TO RELATED APPLICATIONS

This application is a Continuation of International Patent Application No. PCT/JP2024/034392, filed Sep. 26, 2024, which claims the benefit of Japanese Patent Application No. 2023-181052, filed Oct. 20, 2023, both of which are hereby incorporated by reference herein in their entirety.

### BACKGROUND

### Field of the Technology

The present disclosure relates to a cooling device that includes a plurality of evaporators and is capable of simultaneously cooling a plurality of targets. In particular, the present disclosure relates to a cooling device suitably used in industrial equipment including a plurality of heat generation elements having different heat generation amounts.

### Description of the Related Art

In recent years, industrial equipment including a plurality of heat generation elements having different heat generation amounts, including a semiconductor manufacturing device such as an exposure machine, a laser processing machine, and a flat panel display manufacturing device, has been increasing. For example, an exposure machine for semiconductor manufacturing includes components such as an optical system including a light source, a motor, a control circuit, and a power supply, and such components can be regarded as a plurality of heat generation sources having different heat generation amounts. In order to stably operate such industrial equipment in a normal state, a cooling device capable of appropriately cooling the plurality of heat generation sources and peripheral portions thereof according to the heat generation amounts is required.

JP 2004-28354 A describes a refrigerator having three refrigeration cycles. As illustrated in FIG. 8, a refrigerant flow path positioned downstream of a compressor (1) is branched into three flow paths, an expansion valve (4c), an evaporator (5c), and a pressure reducing valve (8c) are connected in series sequentially to a first flow path, an expansion valve (4b), an evaporator (5b), and a pressure reducing valve (8b) are connected in series sequentially to a second flow path, and an expansion valve (4a) and an evaporator (5a) are connected in series sequentially to a third flow path. The three flow paths merge at a position upstream of the compressor (1) to form three refrigeration cycles. (2) represents a condenser, (3) represents a condensed refrigerant tank, (6a) to (6c) represent blowing fans, (9) represents a pressure sensor, and (10) represents a control device.

In each evaporator, an evaporation temperature of a refrigerant that exchanges heat with air in each storage chamber is adjusted so that each storage chamber of the refrigerator has a preset temperature. Specifically, opening degrees of the expansion valve and the pressure reducing valve disposed in each refrigeration cycle are adjusted based on a measurement value of a temperature sensor disposed in each storage chamber, and each evaporator operates at a set evaporation temperature.

Here, the evaporator (5a) disposed in the third flow path where the pressure reducing valve is not disposed has a lower evaporation pressure than the other two evaporators (5b) and (5c). However, even when the evaporation temperatures of the evaporators are different from each other, the evaporation pressures of the evaporator (5b) and the evaporator (5c) are reduced according to the evaporation pressure of the evaporator (5a) using the pressure reducing valve (8b) and the pressure reducing valve (8c).

However, in the refrigeration cycle described in JP 2004-28354 A, control is not performed in consideration of the degree of superheat. Therefore, if the opening degree of the expansion valve is increased to increase a flow rate of the refrigerant in a case where the temperature in the refrigerator increases, there is a risk that the unvaporized refrigerant in the evaporator flows into the compressor in a liquid state. In addition, since the flow rate of the refrigerant is adjusted by changing the opening degree of the expansion valve in order to keep the evaporation temperature constant, the degree of superheat may change within a certain range. Therefore, a phase state of the refrigerant is not stabilized, and the refrigerant may flow into the compressor in a liquid state, which may cause a failure of the compressor.

In addition, for example, in a case where the temperature in the refrigerator increases, when a rotation speed of the compressor is increased to increase the flow rate of the refrigerant in order to improve a cooling capacity of one of the plurality of evaporators, the opening degree of the expansion valve is decreased to keep the evaporation temperature constant following the change. However, when the opening degree of the expansion valve of one refrigeration cycle decreases, the flow rate of the refrigerant flowing into another refrigeration cycle increases. In another refrigeration cycle in which the evaporator having the lowest evaporation pressure is disposed, the opening degree of the expansion valve disposed upstream of the evaporator is decreased following the increase in the flow rate of the refrigerant in order to keep the evaporation temperature constant. As a result, the flow rate of the refrigerant flowing into the evaporator having the lowest evaporation pressure decreases, as a result of which the evaporation pressure decreases. Following the decrease in the evaporation pressure, the opening degree of the pressure reducing valve disposed in another refrigeration cycle is decreased so as to achieve the same pressure as the evaporator having the lowest evaporation pressure. As a result, a large amount of refrigerant flows to the evaporator having the lowest evaporation pressure, and the amount of the refrigerant flowing to another refrigeration cycle is insufficient. Therefore, the temperature in the refrigerator further increases. As a result, the compressor, the expansion valve, and the pressure reducing valve are further subjected to the above-described control repeatedly, and there is a possibility that it becomes uncontrollable.

Further, as disclosed in JP 2004-28354 A, in a configuration in which a plurality of refrigeration cycles connected in parallel exist, control equipment of each refrigeration cycle operates based on a temperature detected by the temperature sensor disposed in each storage chamber. Therefore, the control equipment operates independently in each refrigeration cycle, and thus, the operations of the expansion valves or the operations of the expansion valve and the pressure reducing valve may resonate with each other, causing an unintended rapid refrigerant flow into the evaporator. In this case, hunting may occur, which may lead to an unstable refrigerant flow.

For example, in a cooling device that needs to precisely manage a temperature of a cooling target, such as a cooling device used for a semiconductor exposure device, it is required to achieve, at a high level, a low failure rate, a high responsiveness to a temperature change, and stabilization of a refrigerant flow by suppressing hunting.

### SUMMARY

According to a first aspect of the present disclosure, a cooling device includes a first refrigeration cycle including a compressor configured to compress a refrigerant, a condenser configured to cool and condense the refrigerant compressed by the compressor, a first decompressor, and a first evaporator, and in which the refrigerant decompressed by the first decompressor flows to the first evaporator to cool a first cooling target, a second refrigeration cycle including the compressor, the condenser, a second decompressor, a second evaporator, and an evaporation pressure regulating valve, and in which a refrigerant having a flow rate larger than a flow rate of the first decompressor is decompressed by the second decompressor and flows to the second evaporator to cool a second cooling target, and a control unit. The first refrigeration cycle includes a common flow path in which the compressor and the condenser are connected sequentially and a first flow path in which the first decompressor and the first evaporator are connected sequentially as viewed in a refrigerant flow direction. The second refrigeration cycle includes the common flow path and a second flow path in which the second decompressor, the second evaporator, and the evaporation pressure regulating valve are connected sequentially as viewed in a refrigerant flow direction. The common flow path branches into the first flow path and the second flow path at a branch point positioned downstream of the condenser. The first flow path positioned downstream of the first evaporator and the second flow path positioned downstream of the evaporation pressure regulating valve merge at a junction and are connected to the common flow path positioned upstream of the compressor. The control unit is configured to: control driving of the compressor based on a temperature of the second cooling target cooled by the second evaporator, acquire a first degree of superheat, which is a degree of superheat of the refrigerant, from a temperature and/or a pressure of the refrigerant at a position downstream of the first evaporator in the first flow path, and control an opening/closing degree of the first decompressor based on the first degree of superheat, acquire a second degree of superheat, which is a degree of superheat of the refrigerant, from a temperature and/or a pressure of the refrigerant at a position downstream of the second evaporator in the second flow path, and control an opening/closing degree of the second decompressor based on the second degree of superheat, and control an opening/closing degree of the evaporation pressure regulating valve based on a target pressure of the refrigerant at a position downstream of the evaporation pressure regulating valve or a temperature of the first cooling target cooled by the first evaporator.

According to a second aspect of the present disclosure, a cooling device includes a first refrigeration cycle including a compressor configured to compress a refrigerant, a condenser configured to cool and condense the refrigerant compressed by the compressor, a first decompressor, a first evaporator, and an evaporation pressure regulating valve, and in which the refrigerant decompressed by the first decompressor flows to the first evaporator to cool a first cooling target, a second refrigeration cycle including the compressor, the condenser, a second decompressor, and a second evaporator, and in which a refrigerant having a flow rate larger than a flow rate of the first evaporator flows to the second evaporator to cool a second cooling target, and a control unit. The first refrigeration cycle includes a common flow path in which the compressor and the condenser are connected sequentially and a first flow path in which the first decompressor, the first evaporator, and the evaporation pressure regulating valve are connected sequentially as viewed in a refrigerant flow direction. The second refrigeration cycle includes the common flow path, a second flow path in which the second decompressor and the second evaporator are connected sequentially, and a hot gas bypass that branches from the common flow path between the compressor and the condenser and is connected to the second flow path between the second decompressor and the second evaporator via a control valve as viewed in a refrigerant flow direction. The common flow path branches into the first flow path and the second flow path at a branch point positioned downstream of the condenser. The first flow path positioned downstream of the evaporation pressure regulating valve and the second flow path positioned downstream of the second evaporator merge at a junction and are connected to the common flow path positioned upstream of the compressor. The control unit is configured to: control an opening/closing degree of the control valve of the hot gas bypass based on a temperature of the second cooling target cooled by the second evaporator, acquire a first degree of superheat, which is a degree of superheat of the refrigerant, from a temperature and/or a pressure of the refrigerant at a position downstream of the first evaporator in the first flow path, and control an opening/closing degree of the first decompressor based on the first degree of superheat, acquire a second degree of superheat, which is a degree of superheat of the refrigerant, from a temperature and/or a pressure of the refrigerant at a position downstream of the second evaporator in the second flow path, and control an opening/closing degree of the second decompressor based on the second degree of superheat, and control an opening/closing degree of the evaporation pressure regulating valve based on a target pressure of the refrigerant at a position downstream of the evaporation pressure regulating valve.

Features of the present disclosure will become apparent from the following description of embodiments with reference to the attached drawings. The following description of embodiments is described by way of example.

### BRIEF DESCRIPTION OF THE DRAWINGS

FIG. 1 is a diagram illustrating a configuration of a cooling device according to a first embodiment.

FIG. 2 is a block diagram illustrating a configuration of a control unit of the first embodiment.

FIG. 3 is a diagram illustrating a configuration of a cooling device according to a second embodiment.

FIG. 4 is a diagram illustrating a configuration of a cooling device according to a third embodiment.

FIG. 5 is a diagram illustrating a configuration of industrial equipment according to a fourth embodiment.

FIG. 6 is a diagram illustrating a configuration of a cooling device according to a fifth embodiment.

FIG. 7A is a table illustrating moving average processing in a sixth embodiment.

FIG. 7B is a graph illustrating the moving average processing in the sixth embodiment.

FIG. 8 is a diagram illustrating a conventionally known refrigerator.

### DESCRIPTION OF THE EMBODIMENTS

### First Embodiment

### Configuration of Cooling Device

Hereinafter, a cooling device 101 according to a first embodiment will be described with reference to the drawings.

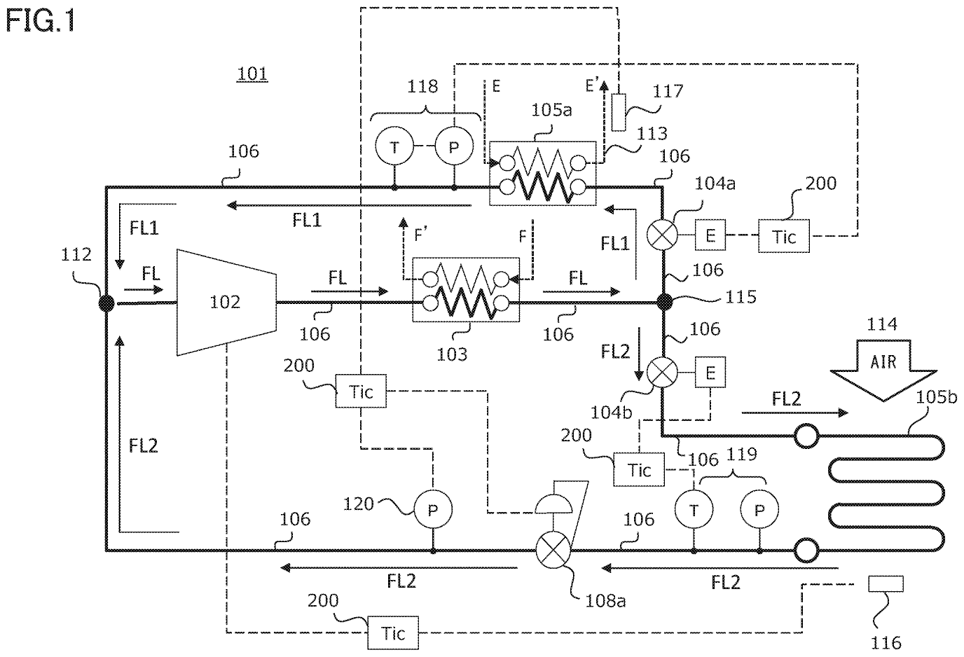

In FIG. 1, a thick line indicates a refrigerant flow path formed through a refrigerant pipe 106. The cooling device 101 has two refrigeration cycles (refrigerant circulation paths) provided in parallel, and the two refrigeration cycles share a compressor 102 and a condenser 103. The refrigeration cycle (refrigerant circulation path) referred to herein refers to a cycle in which a refrigerant is circulated in an order of “compressor→condenser→decompressor (expansion valve)→evaporator” while undergoing a phase change in order to achieve a function of the cooling device. Regardless of the name “refrigeration cycle”, the refrigeration cycle does not necessarily mean freezing.

In FIG. 1, a flow of the refrigerant in each portion of the refrigerant flow path is schematically indicated by arrows as a refrigerant flow FL, a refrigerant flow FL1, and a refrigerant flow FL2, and a direction of the arrow indicates a direction in which the refrigerant flows. The refrigerant flow FL flowing through the compressor 102 and the condenser 103 branches into the refrigerant flow FL1 and the refrigerant flow FL2 at a branch point 115 disposed downstream of the condenser 103. The refrigerant flow FL1 and the refrigerant flow FL2 merge at a junction 112 disposed upstream of the compressor 102 to become the refrigerant flow FL, and flow into the compressor 102.

The refrigerant flow FL1 passes through a decompressor 104a, an evaporator 105a, and a detection unit 118 in this order. The compressor 102, the condenser 103, the decompressor 104a, and the evaporator 105a form a first refrigeration cycle.

The refrigerant flow FL2 passes through a decompressor 104b, an evaporator 105b, a detection unit 119, an evaporation pressure regulating valve 108a, and a pressure detection unit 120 in this order. The compressor 102, the condenser 103, the decompressor 104b, the evaporator 105b, and the evaporation pressure regulating valve 108a form a second refrigeration cycle.

A flow path from the junction 112 to the branch point via the compressor 102 and the condenser 103 is shared by the first refrigeration cycle and the second refrigeration cycle, and thus can be referred to as a common flow path. In the first refrigeration cycle, a flow path from the branch point to the junction including the decompressor 104a (first decompressor) and the evaporator 105a (first evaporator) as viewed in a refrigerant flow direction can be referred to as a first flow path. In the second refrigeration cycle, a flow path from the branch point to the junction including the decompressor 104b (second decompressor), the evaporator 105b (second evaporator), and the evaporation pressure regulating valve 108a as viewed in a refrigerant flow direction can be referred to as a second flow path. In addition, the detection unit 118 can be referred to as first detection means, the detection unit 119 can be referred to as second detection means, the pressure detection unit 120 can be referred to as third detection means, a temperature detection unit 117 can be referred to as a first temperature detection unit, and a temperature detection unit 116 can be referred to as a second temperature detection unit. A cooling target 113 can be referred to as a first cooling target, and a cooling target 114 can be referred to as a second cooling target.

In the cooling device 101 according to the present embodiment, the evaporator 105a disposed in the first refrigeration cycle and the evaporator 105b disposed in the second refrigeration cycle are used to cool different targets. The evaporator 105b is used to cool a target that requires temperature management to be performed with high accuracy and high response speed. The evaporator 105a is used to cool a target for which relatively low accuracy or response speed in temperature management is acceptable.

The second refrigeration cycle is configured as a circuit for cooling a cooling target that needs to be kept at a constant temperature with high accuracy, and is configured to have a higher cooling capacity than the first refrigeration cycle. Therefore, a flow rate of the refrigerant flow FL2 flowing through the second refrigeration cycle is larger than a flow rate of the refrigerant flow FL1 flowing through the first refrigeration cycle.

For example, in a case where the cooling device 101 according to the embodiment is installed for a semiconductor manufacturing device, the evaporator 105b disposed in the second refrigeration cycle is suitably used as a cooler for keeping a temperature of an atmosphere (for example, air circulating in an optical unit and a chamber) in the semiconductor manufacturing device constant. In order to ensure accuracy of an optical system of a pattern exposure machine, the atmosphere (air) in the semiconductor manufacturing device needs to be managed such that the temperature remains within a range of ±0.01° C. of a set temperature, for example. In the present embodiment, as described below, the evaporator 105b disposed in the second refrigeration cycle is configured to quickly respond to a temperature change of air to be cooled. In order to prevent moisture or frost from adhering due to dew condensation or ice formation caused by heat exchange with the air, leading to a failure of the semiconductor manufacturing device, the evaporator 105b is controlled to perform heat exchange at a high evaporation pressure (evaporation temperature).

The evaporator 105a disposed in the first refrigeration cycle is suitably used as a cooler that cools a liquid refrigerant (for example, a fluorine-based inert liquid) for cooling a driving unit and a light source unit serving as heat sources in the semiconductor manufacturing device. Temperatures of the driving unit and the light source unit serving as the heat sources in the semiconductor manufacturing device do not need to be controlled with as high of an accuracy as the air in the device, and it is sufficient if the liquid refrigerant for cooling the heat sources does not have a certain temperature or higher. The evaporator 105a is thus controlled to cool the liquid refrigerant so as not to reach a certain temperature or higher.

Next, the components included in the cooling device 101 will be sequentially described.

A control unit 200 is a computer for controlling an operation of the cooling device 101. Although the control unit 200 is illustrated as being distributed in FIG. 1, such distribution is merely schematically represented by connection of dotted lines to facilitate understanding of a relationship between a control target and detection means (for example, a sensor) for acquiring information necessary for control, and the control unit 200 is not necessarily physically distributed. For example, a specific form of distribution or integration of the control unit 200 is not limited to the illustrated example, and all or part of the control unit 200 can be functionally or physically distributed and integrated in arbitrary units according to a use situation or the like. The control unit 200 can be configured using hardware or software.

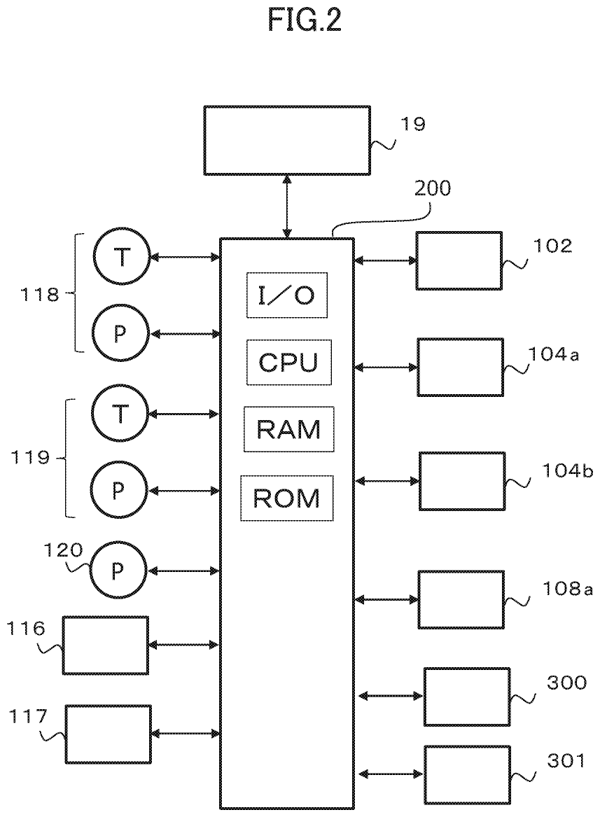

FIG. 2 is a simple block diagram for describing a connection relationship between the control unit 200 and each element. For convenience of illustration, FIG. 2 illustrates only elements necessary for describing the technology according to the present disclosure among the control target to be controlled by the control unit 200 and the detection means for acquiring information necessary for control. The control unit 200 is a computer for controlling the operation of the cooling device 101, and includes a central processing unit (CPU), a read only memory (ROM), a random access memory (RAM), an input/output (I/O) port, and the like therein.

The ROM stores a basic operation program of the cooling device 101. A control program for controlling an operation of the control target (the compressor 102, the decompressor 104a, the decompressor 104b, the evaporation pressure regulating valve 108a, and the like) based on information input from the detection means (the detection unit 118, the detection unit 119, the pressure detection unit 120, the temperature detection unit 116, the temperature detection unit 117, and the like) provided at each portion is also stored in the ROM. However, such programs may also be loaded into the RAM from the outside via a network, or may be loaded into the RAM via a computer-readable recording medium. As a specific example, a flexible disk, an optical disk, a magneto-optical disk, a magnetic tape, or a USB memory, a solid-state drive (SSD), or the like can be used as the recording medium.

The I/O port of the control unit 200 is connected to external equipment 19 including an external computer and the network. The control unit 200 can input and output data necessary for controlling cooling, such as a heat generation amount and an allowable temperature range of each unit of industrial equipment to be cooled by the cooling device 101, to and from an external computer via the I/O port.

An operation unit 300 and a display unit 301 are connected to the control unit 200 as user interface (UI) devices. The operation unit 300 can be implemented by a terminal such as a handy terminal or a device such as a keyboard, a jog dial, a mouse, a pointing device, a voice input device, or a control terminal including such devices. The display unit 301 only needs to be capable of displaying information related to various types of processing executed by the control unit 200 on a display screen, and for example, a liquid crystal display device or an organic EL device can be used.

When creating, editing, confirming, or the like a program or a parameter (for example, a proportional constant of proportional-integral-differential (PID) control) for performing the PID control described below, a user can input the program or data through the operation unit 300 and can display the program or data on the display unit 301.

The compressor 102 (FIG. 1) sucks and compresses the refrigerant used in the cooling device 101, changes the refrigerant to a high-temperature and high-pressure gaseous state, and discharges the refrigerant to a downstream side. Although not illustrated, a gas-liquid separator may be provided in front of a suction port of the compressor 102. In the present embodiment, an inverter-controlled compressor is suitably used as the compressor 102. This is because the inverter-controlled compressor can change a discharge amount of the refrigerant with high responsiveness by controlling a rotation speed using an inverter. In this case, when the PID control described below is performed, the control unit 200 sends a command for controlling a frequency of the inverter to the compressor 102 to control the discharge amount of the refrigerant from the compressor 102. As a result, effectively high control responsiveness is ensured for the compressor 102.

The condenser 103 causes a cooling liquid to flow between F and F′ to cool and condense superheated vapor discharged from the compressor 102. The refrigerant in a liquefied state, which is condensed by the condenser 103, flows into the branch point 115 through the refrigerant pipe 106. Although not illustrated, a liquid receiver may be disposed between the condenser 103 and the branch point 115.

The decompressor 104a disposed in the first refrigeration cycle and the decompressor 104b disposed in the second refrigeration cycle, which are positioned downstream of the branch point 115, are decompressors that decompresses the high-pressure liquefied refrigerant condensed by the condenser 103 so as to transition to a low-temperature and low-pressure gas-liquid mixed state (gas-liquid two-phase state). In the present embodiment, electronically controlled expansion valves are used for the decompressor 104a and the decompressor 104b. The electronically controlled expansion valve has a wider controllable opening degree range than a mechanically controlled expansion valve, and has a higher response speed in control. Therefore, as in the present embodiment, the electronically controlled expansion valve is particularly suitable in a system in which the flow rate of the refrigerant flowing through the entire circuit of the refrigeration cycle greatly changes due to a change in the rotation speed of the compressor 102. When the PID control described below is performed, the control unit 200 sends a command for independently controlling opening and closing of each of the decompressor 104a and the decompressor 104b.

In the first refrigeration cycle, the evaporator 105a disposed downstream of the decompressor 104a cools the liquid (cooling target) flowing in from a pipe E and flowing out to E′ by using the refrigerant flowing in from the decompressor 104a. Specific examples of the liquid (cooling target) can include the liquid (for example, a fluorine-based inert liquid) for cooling the driving unit and the light source unit, which are the heat sources in the semiconductor manufacturing device, as described above. As described above, in the evaporator 105a, the refrigerant in the decompressed gas-liquid mixed state is used to take heat from the high-temperature cooling target flowing in from the pipe E, and the cooled cooling target is caused to flow out to E′. When taking the heat from the cooling target, the refrigerant evaporates and changes to high-temperature and low-pressure gas, and returns to the compressor 102 via the junction 112.

The detection unit 118 disposed downstream of the evaporator 105a in the first refrigeration cycle includes a temperature sensor that detects a temperature of the refrigerant flowing out of the evaporator 105a, a pressure sensor that detects a pressure of the refrigerant, and a transmission unit that transmits temperature and pressure detection results to the control unit 200.

In the second refrigeration cycle, the evaporator 105b disposed downstream of the decompressor 104b cools air flowing in as the cooling target 114 by using the refrigerant flowing in from the decompressor 104b. As a specific example of the cooling target 114, an atmosphere (for example, air circulating in the optical unit and the chamber) in the semiconductor manufacturing device can be exemplified. As described above, the evaporator 105b cools the high-temperature cooling target 114 by taking heat from the high-temperature cooling target 114 using the decompressed refrigerant in the gas-liquid mixed state. When taking the heat from the cooling target, the refrigerant evaporates and changes to saturated vapor, and returns to the compressor 102 via the junction 112.

In the second refrigeration cycle, in order to prevent dew condensation from occurring in peripheral equipment when the refrigerant passes through the evaporator 105b and exchanges heat with the cooling target 114, it is necessary to perform heat exchange in the evaporator 105b in a state close to an ambient atmosphere in which the cooling device 101 is installed. Therefore, the evaporator 105b is configured to exchange heat with the cooling target 114 at an evaporation pressure higher than that of the evaporator 105a in the first refrigeration cycle. With such a configuration, a difference between a pressure at an outlet of the evaporator 105a and a pressure at an outlet of the evaporator 105b becomes large, as a result of which refrigerant merging at the junction 112 may become unstable. When the flow of the refrigerant becomes unstable, controllability of heat exchange may decrease, and the temperature of the cooling target may fluctuate, and in some cases, it may be impossible to achieve a necessary cooling capacity. In particular, in a cooling device that cools a device requiring highly accurate temperature management such as a semiconductor manufacturing device, it is not preferable that the flow of the refrigerant becomes unstable.

According to the present embodiment, the evaporation pressure regulating valve 108a is disposed downstream of evaporator 105b and upstream of the junction 112 in the second refrigeration cycle along the refrigerant flow FL2. An electronically controlled expansion valve may be used as the evaporation pressure regulating valve 108a. The control unit 200 controls an opening degree of the evaporation pressure regulating valve 108a to reduce the pressure of the refrigerant flowing out of the evaporator 105b to a pressure equivalent to the pressure of the refrigerant flowing out of the evaporator 105a. As a result, a pressure difference between the refrigerant flow FL2 and the refrigerant flow FL1 at the junction 112 is reduced, and controllability and stability of a cooling operation can be improved.

In the present embodiment, the temperature detection unit 116 that detects a temperature of the cooling target 114 cooled by the evaporator 105b is disposed downstream of the evaporator 105b as viewed in a direction in which the cooling target 114 flows. The temperature detection unit 116 includes a temperature sensor that detects the temperature of the cooling target 114 and a transmission unit that transmits a detection result to the control unit 200.

The detection unit 119 that detects the temperature and the pressure of the refrigerant flowing out of the evaporator 105b is disposed downstream of the evaporator 105b in the second refrigeration cycle. The detection unit 119 includes a temperature sensor, a pressure sensor, and a transmission unit that transmits temperature and pressure detection results to the control unit 200.

### Operation of Cooling Device

Next, the operation of the cooling device 101 will be described. The control unit 200 controls driving of the compressor 102 based on the temperature of the cooling target 114 detected by the temperature detection unit 116, that is, the temperature of the cooling target 114 cooled by the evaporator 105b in the second refrigeration cycle. Specifically, the control unit 200 performs control to change the discharge amount of the refrigerant from the compressor 102 by changing the rotational speed (rotation speed per unit time) of the compressor 102 based on the detection result of the temperature detection unit 116.

In a case where the temperature of the cooling target 114 increases to be higher than a preset temperature, the control unit 200 performs control to increase the rotational speed of the compressor 102 to increase the flow rate of the refrigerant flowing through the entire circuit. Increasing the flow rate of the refrigerant leads to an increase in the heat exchange per unit time, which prompts taking more heat from the cooling target 114. When the temperature of the cooling target is lower than the preset temperature, the control unit 200 performs control to decrease the rotational speed of the compressor 102 to decrease the flow rate of the refrigerant flowing through the entire circuit. Decreasing the flow rate of the refrigerant leads to a decrease in the heat exchange per unit time, so that the cooling target 114 is prevented from being cooled more than necessary.

The control unit 200 performs control to change an opening degree of the decompressor 104a based on the degree of superheat (first degree of superheat) of the refrigerant flowing out of the evaporator 105a. The degree of superheat of the refrigerant flowing out of the evaporator 105a is calculated based on the temperature or pressure of the refrigerant detected by the detection unit 118 positioned downstream of the evaporator 105a. In a case where the calculated degree of superheat is higher than a preset degree of superheat, the control unit 200 performs control to increase the opening degree of the decompressor 104a to increase the flow rate of the refrigerant flowing into the evaporator 105a in order to reduce the degree of superheat. In a case where the degree of superheat is lower than the preset degree of superheat, it is necessary to reliably vaporize the refrigerant flowing out of the evaporator to prevent liquid floodback to the compressor. Therefore, the control unit 200 performs control to decrease the opening degree of the decompressor 104a to reduce the flow rate of the refrigerant flowing into the evaporator 105a.

The control unit 200 performs control to change the opening degree of the decompressor 104b based on the degree of superheat (second degree of superheat) of the refrigerant flowing out of the evaporator 105b. The degree of superheat of the refrigerant flowing out of the evaporator 105b is calculated based on the temperature or pressure of the refrigerant detected by the detection unit 119 positioned downstream of the evaporator 105b. In a case where the calculated degree of superheat is higher than a preset degree of superheat, the control unit 200 performs control to increase the opening degree of the decompressor 104b to increase the flow rate of the refrigerant flowing into the evaporator 105b in order to reduce the degree of superheat. In a case where the degree of superheat is lower than the preset degree of superheat, it is necessary to reliably vaporize the refrigerant flowing out of the evaporator to prevent liquid floodback to the compressor. Therefore, the control unit 200 performs control to decrease the opening degree of the decompressor 104b to reduce the flow rate of the refrigerant flowing into the evaporator 105b.

When the control unit 200 acquires the degree of superheat of the refrigerant, the degree of superheat may be obtained by calculation using the detected temperature or pressure of the refrigerant, or may be obtained by storing a correspondence relationship between a detected value and the degree of superheat in advance as a lookup table and referring to the lookup table.

As described above, the control unit 200 controls the first refrigeration cycle such that the degree of superheat of the refrigerant flowing out of the evaporator 105a becomes a preset value. The evaporation pressure regulating valve 108a of the second refrigeration cycle is controlled such that a pressure of the refrigerant on an outlet side of the evaporator 105a controlled so as to achieve the set degree of superheat and a pressure detected by the pressure detection unit 120 of the second refrigeration cycle become equal to each other.

In other words, the pressure of the refrigerant flowing out of the evaporator 105a so as to make the degree of superheat have a predetermined value is set as an outlet pressure (target pressure) of the evaporation pressure regulating valve 108a, and the opening degree of the evaporation pressure regulating valve 108a is controlled. Specifically, the set target pressure is compared with the pressure detected by the pressure detection unit 120, and the opening and closing of the evaporation pressure regulating valve 108a is controlled such that the values become equal to each other. With such control, the pressure of the refrigerant flowing out of the evaporation pressure regulating valve 108a is regulated to be substantially equal to the pressure of the refrigerant flowing out of the evaporator 105a, so that the refrigerant merging at the junction 112 is stabilized. The evaporation pressure regulating valve 108a may be feedback-controlled such that the pressure detected by the detection unit 118 and the pressure detected by the pressure detection unit 120 have the same value.

The opening degree of the evaporation pressure regulating valve 108a may be controlled not by the pressure detection unit 120 disposed downstream of the evaporation pressure regulating valve 108a but by the temperature detection unit 117 that detects the temperature of the cooling target 113 after heat exchange by the evaporator 105a. This is because, as described below, there is a correlation between the temperature detected by the temperature detection unit 117 and the pressure of the refrigerant regulated by the evaporation pressure regulating valve 108a.

For example, if the opening degree of the evaporation pressure regulating valve 108a is increased, a pressure loss due to the evaporation pressure regulating valve 108a decreases, and at the same time, the amount of the refrigerant flowing into the evaporator 105a decreases, as a result of which the temperature of the cooling target 113 detected by the temperature detection unit 117 increases. On the other hand, if the opening degree of the evaporation pressure regulating valve 108a is decreased, the pressure loss due to the evaporation pressure regulating valve 108a increases, and at the same time, the amount of the refrigerant flowing into the evaporator 105a increases, as a result of which the temperature of the cooling target 113 detected by the temperature detection unit 117 decreases. In this manner, the pressure loss occurring in the evaporation pressure regulating valve 108a and the amount of the refrigerant flowing into the evaporator 105a are changed according to the opening degree of the evaporation pressure regulating valve 108a. Therefore, a pressure on a downstream side of the evaporation pressure regulating valve 108a and the temperature of the cooling target 113 detected by the temperature detection unit 117 can be regulated by the opening degree of the evaporation pressure regulating valve 108a. That is, if the evaporation pressure regulating valve 108a is controlled such that the temperature detected by the temperature detection unit 117 becomes a preset temperature, the pressure on the downstream side of the evaporation pressure regulating valve 108a becomes a pressure corresponding to the temperature detected by the temperature detection unit 117.

In order to bring the pressure of the refrigerant flowing out of the evaporator 105a and the pressure of the refrigerant decompressed by the evaporation pressure regulating valve 108a close to each other to stabilize the flow of the refrigerant flowing into the junction 112, it is sufficient if the evaporation pressure regulating valve 108a is controlled based on the temperature detected by the temperature detection unit 117 using the correlation described above.

That is, since the pressure of the refrigerant flowing out of the evaporator 105a is determined by setting the degree of superheat of the refrigerant flowing out of the evaporator 105a in advance, a target value (target temperature) of the temperature detected by the temperature detection unit 117 is set such that the pressure becomes equal to the pressure on the downstream side of the evaporation pressure regulating valve 108a.

It is sufficient if the control unit 200 controls the opening degree of the evaporation pressure regulating valve 108a such that the temperature detected by the temperature detection unit 117 becomes the target temperature. With such control, a pressure on a downstream side of the evaporator 105a and the pressure on the downstream side of the evaporation pressure regulating valve 108a have substantially the same value, so that the merging at the junction 112 is stabilized. Installing the temperature detection unit 117 and adjusting the opening degree of the evaporation pressure regulating valve 108a not only contribute to stabilization of the merging at the junction 112 but also change a cooling capacity of the evaporator 105a to keep the temperature of the cooling target 113 constant. As a result, in the evaporator 105a, it is unnecessary to adjust the temperature of the cooling target by providing temperature adjustment equipment such as a heater on an inflow side or an outflow side of the cooling target, which can contribute to cost reduction, downsizing of the device, and energy saving.

In the present embodiment, the operations of the compressor 102, the decompressor 104a, the decompressor 104b, and the evaporation pressure regulating valve 108a are controlled using the PID control.

When the control unit 200 performs the PID control on the operation (rotational speed S1) of the compressor 102, the following Mathematical Formula 1 is used.

$$S 1 = {K}_{p 1} \cdot Δ P 1 + {K}_{i 1} \cdot \int Δ P 1 \cdot dt + \frac{Δ P 1}{Δ t} \cdot {K}_{d 1} \qquad Mathematical Formula 1$$

Here, S1 represents the rotational speed of the compressor 102, and ΔP1 represents a deviation between the target temperature of the cooling target 114 (for example, the air) cooled by the evaporator 105b and the temperature detected by the temperature detection unit 116.

When the control unit 200 performs the PID control on the operation (opening degree S2) of the decompressor 104b, the following Mathematical Formula 2 is used.

$$S 2 = {K}_{p 2} \cdot Δ P 2 + {K}_{i 2} \cdot \int Δ P 2 \cdot dt + \frac{Δ P 2}{Δ t} \cdot {K}_{d 2} \qquad Mathematical Formula 2$$

Here, S2 represents the opening degree of the decompressor 104b, and ΔP2 represents a deviation between the degree of superheat of the refrigerant calculated based on the detection result of the detection unit 119 and the set degree of superheat.

When the control unit 200 performs the PID control on the operation (opening degree S3) of the decompressor 104a, the following Mathematical Formula 3 is used.

$$S 3 = {K}_{p 3} \cdot Δ P 3 + {K}_{i 3} \cdot \int Δ P 3 \cdot dt + \frac{Δ P 3}{Δ t} \cdot {K}_{d 3} \qquad Mathematical Formula 3$$

Here, S3 represents the opening degree of the decompressor 104a, and ΔP3 represents a deviation between the degree of superheat of the refrigerant calculated based on the detection result of the detection unit 118 and the set degree of superheat.

When the control unit 200 performs the PID control on the operation (opening degree S4) of the evaporation pressure regulating valve 108a, the following Mathematical Formula 4 is used.

$$S 4 = {K}_{p 4} \cdot Δ P 4 + {K}_{i 4} \cdot \int Δ P 4 \cdot dt + \frac{Δ P 4}{Δ t} \cdot {K}_{d 4} \qquad Mathematical Formula 4$$

S4 represents the opening degree of the evaporation pressure regulating valve 108a, and ΔP4 represents a deviation between the detection result of the pressure detection unit 120 and the target pressure. ΔP4 may also represent a deviation between the target temperature of the cooling target 113 and the detection result of the temperature detection unit 117.

Constants Kₚ₁, Kₚ₂, Kₚ₃, and Kₚ₄ for proportional control of the compressor 102, the decompressor 104b, the decompressor 104a, and the evaporation pressure regulating valve 108a in Mathematical Formulas 1 to 4 above are set so as to satisfy a relationship of the following Mathematical Formula 5.

$${K}_{p 1} > {K}_{p 2} > {K}_{p 3} > {K}_{p 4} \qquad Mathematical Formula 5$$

With such a setting, a control response speed RS1 of the compressor 102 can be made higher than any of a control response speed RS2 of the decompressor 104b, a control response speed RS3 of the decompressor 104a, and a control response speed RS4 of the evaporation pressure regulating valve 108a. The control response speed RS2 of the decompressor 104b can be made lower than the control response speed RS1 of the compressor 102 and higher than the control response speed RS3 of the decompressor 104a and the control response speed RS4 of the evaporation pressure regulating valve 8a. In addition, the control response speed RS3 of the decompressor 104a can be made lower than the control response speed RS1 of the compressor 102 and the control response speed RS2 of the decompressor 104b and higher than the control response speed RS4 of the evaporation pressure regulating valve 8a. Further, the control response speed RS4 of the evaporation pressure regulating valve 108a can be made lower than any of the control response speed RS1 of the compressor 102, the control response speed RS2 of the decompressor 104b, and the control response speed RS3 of the decompressor 104a.

In the present embodiment, by enabling the compressor 102 to be controlled at the highest speed, the cooling capacity of the evaporator 105b can be precisely controlled according to the temperature change of the cooling target 114 (for example, the air), and thus, it is possible to precisely control the temperature of the cooling target 114 so as to remain within a range of ±0.1° C. of the target temperature, for example.

Since the decompressor 104b is disposed upstream of the evaporator 105b requiring a higher cooling capacity than the evaporator 105a, it is necessary to allow a larger amount of refrigerant to flow into the evaporator 105b than the amount of the refrigerant flowing into the evaporator 105a by the decompressor 104a. Therefore, there is a higher possibility that the refrigerant returns to the compressor 102 in the gas-liquid two-phase state in the second refrigeration cycle than in the first refrigeration cycle.

Therefore, in order to stabilize the degree of superheat of the refrigerant positioned downstream of the evaporator 105b at a preset value, it is necessary to control the opening degree of the decompressor 104b to quickly follow the state of the refrigerant flowing out of the evaporator 105b. If the control response speed of the decompressor 104a is made higher than that of the decompressor 104b, the opening degree of the decompressor 104b having a low control response speed changes even while the opening degree of the decompressor 104a is tending to converge to a certain opening degree. When the opening degree of the decompressor 104b changes in this manner, the amount of the refrigerant flowing into the evaporator 105a also changes, and thus, the degree of superheat further fluctuates, and there is a possibility that the control of the decompressor 104a fails to converge, causing hunting.

On the other hand, if the control response speed of the decompressor 104b is made higher than that of the decompressor 104a, even when the opening degree of the decompressor 104a changes while the opening degree of the decompressor 104b is tending to converge to a certain opening degree, the change in the amount of refrigerant flowing into the decompressor 104b caused by the change of the decompressor 104a does not become an amount that greatly changes the degree of superheat. Therefore, the control of the decompressor 104b is less likely to diverge.

The proportional constant Kₚ₂ of the decompressor 104b can be set small to such an extent that the degree of superheat of the evaporator 105b can be kept constant. Since the decompressor 104a is disposed upstream of the evaporator 105a that does not require precise temperature adjustment as compared with the evaporator 105b, the control response speed does not need to be higher than that of the decompressor 104b.

The opening degree of the evaporation pressure regulating valve 108a is controlled based on the pressure on the downstream side of the evaporation pressure regulating valve 108a detected by the pressure detection unit 120 or the temperature of the cooled cooling target 113 detected by the temperature detection unit 117. If the evaporation pressure regulating valve 108a is controlled at a control response speed higher than that of the decompressor 104a disposed upstream of the evaporator 105a, the decompressor 104a disposed upstream may fail to follow the change in the flow rate of the refrigerant accompanying the change in the opening degree of the evaporation pressure regulating valve 108a and may fail to maintain the preset degree of superheat. Similarly, if the evaporation pressure regulating valve 108a is controlled at a control response speed higher than that of the decompressor 104b disposed upstream of the evaporator 105b, the decompressor 104b may fail to follow the change in the refrigerant flow rate accompanying the change in the opening degree of the evaporation pressure regulating valve 108a and fail to maintain the preset degree of superheat. Since the evaporation pressure regulating valve 108a has the lowest control response speed among the respective pieces of control equipment, the opening degree of the evaporation pressure regulating valve 108a can be adjusted following low-frequency pressure fluctuations remaining in the refrigerant that has passed through the evaporator 105b, and the state of the refrigerant can be further stabilized.

As described above, when the control response speed while performing the PID control on each piece of control equipment is set to increase sequentially from an upstream side and in descending order of the flow rate of the refrigerant, hunting can be prevented, the flow of the refrigerant is stabilized, and precise temperature control can be performed. In the present embodiment, the control response speed of each piece of control equipment is adjusted by the proportional constant of the PID control, but other means may be used as long as the control response speed of each piece of control equipment can be set in the above-described order.

The control response speed of the control target may be changed by changing any one of values Kᵢ₁ to Kᵢ₄ and K_{d1} to K_{d4} in (Mathematical Formula 1) to (Mathematical Formula 4). Kᵢ₁ to Kᵢ₄ and K_{d1} to K_{d4} can be determined by a method called a transient response method in order to stabilize control.

### Second Embodiment

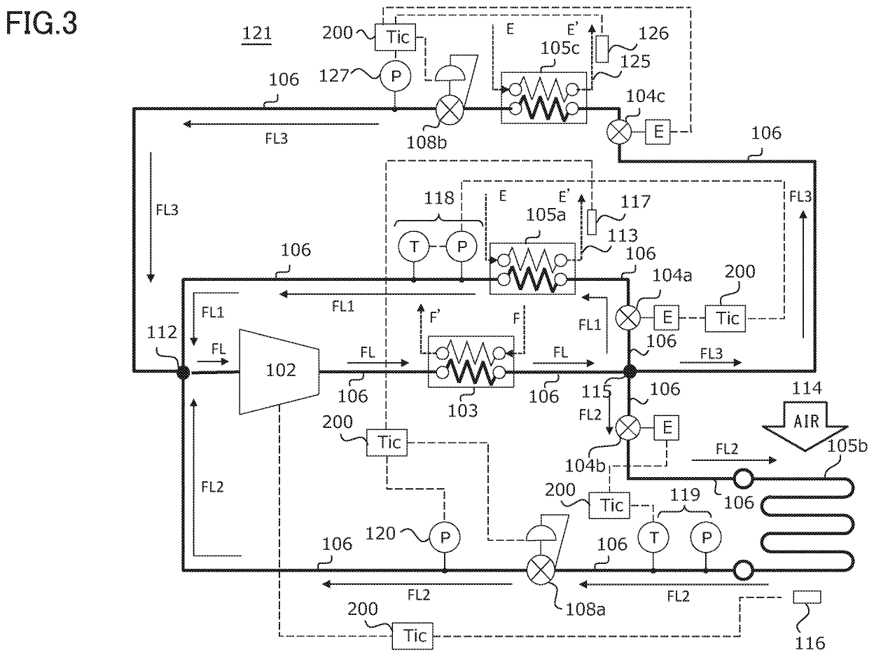

A cooling device 121 according to a second embodiment will be described with reference to FIG. 3. A description of matters common to the first embodiment will be simplified or omitted. The cooling device 121 of the second embodiment illustrated in FIG. 3 is provided with a third refrigeration cycle branching from a branch point 115 in addition to the first refrigeration cycle and the second refrigeration cycle in the first embodiment. That is, a decompressor 104c (third decompressor), an evaporator 105c (third evaporator), and an evaporation pressure regulating valve 108b (second evaporation pressure regulating valve) are connected in series from the branch point 115 toward a junction 112 via a refrigerant pipe 106. A refrigerant flow FL3 flowing through such a flow path and a refrigerant flow FL flowing through a compressor 102 and a condenser 103 form the third refrigeration cycle.

In the present embodiment, a control unit 200 fixes an opening degree of the decompressor 104c such that an evaporation pressure of the evaporator 105c becomes higher than an evaporation pressure of an evaporator 105a and lower than an evaporation pressure of an evaporator 105b. When the evaporation pressure of the evaporator 105c is controlled to change, the evaporation pressure of the evaporator 105c may become higher than the evaporation pressure in the evaporator 105b, or the evaporation pressure of the evaporator 105c may become lower than the evaporation pressure of the evaporator 105a in a case where a temperature of a cooling target 125 (third cooling target) greatly changes. That is, an amount of a refrigerant flowing into the evaporator 105c may become the largest or the amount of the refrigerant flowing into the evaporator 105c may become the smallest. In this case, it is necessary to change the order of the control response speeds of respective pieces of equipment, which may complicate the control. In order to avoid such a problem, in the present embodiment, the evaporation pressure of the evaporator 105c is fixed. At this time, the opening degree of the decompressor 104c is set such that the refrigerant flowing out of the evaporator 105c has a constant degree of superheat, whereby it is possible to prevent liquid floodback to the compressor 102. In this example, an electronically controlled valve is used as the decompressor 104c, and the opening degree of the decompressor 104c is fixed to a predetermined opening degree under the control of the control unit 200. However, a mechanical valve whose opening degree is adjusted and fixed in advance may also be used.

The control unit 200 adjusts an opening degree of the evaporation pressure regulating valve 108b based on the temperature of the cooling target 125 detected by a temperature detection unit 126 and a refrigerant pressure at a position downstream of the evaporation pressure regulating valve 108b detected by a pressure detection unit 127 so as to keep the evaporation pressure at a predetermined constant value. As described in the first embodiment, the control response speed for adjusting the opening degree of the evaporation pressure regulating valve 108b is set so as to increase sequentially from an upstream side and in descending order of a flow rate of the refrigerant. As a result, hunting can be suppressed, and a flow of the refrigerant is stabilized, so that a temperature of a cooling target 114 cooled by the evaporator 105b can be precisely adjusted. Since the evaporation pressure regulating valve 108b only needs to be able to keep the evaporation pressure of the evaporator 105c constant, the opening degree of the evaporation pressure regulating valve 108b may be controlled based on only a measurement result of the temperature detection unit 126 or only a measurement result of the pressure detection unit 127.

### Third Embodiment

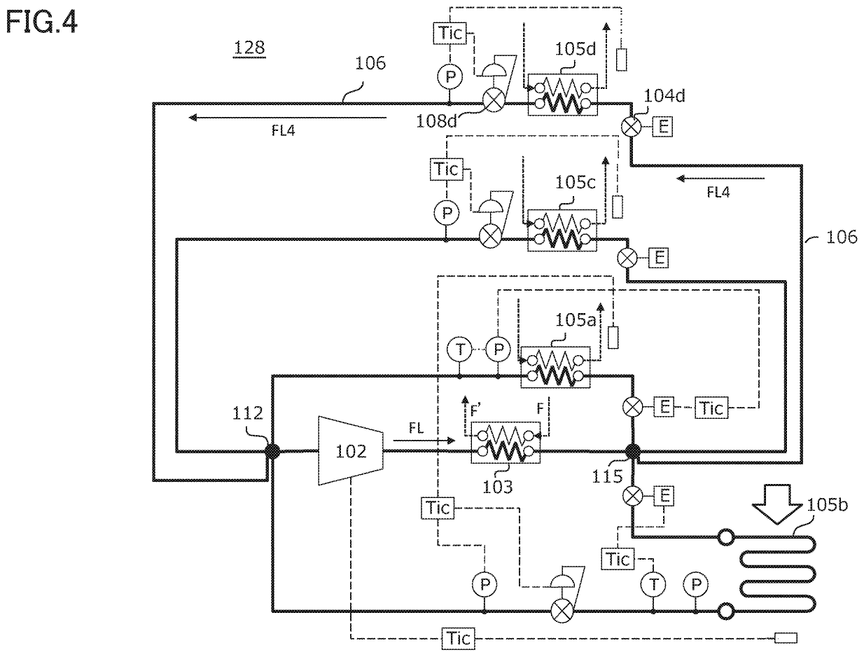

A cooling device 128 according to a third embodiment will be described with reference to FIG. 4. A description of matters common to the first or second embodiment will be simplified or omitted. The cooling device 128 of the third embodiment illustrated in FIG. 4 is provided with a fourth refrigeration cycle branching from a branch point 115 in addition to the first refrigeration cycle, the second refrigeration cycle, and the third refrigeration cycle of the second embodiment. That is, a decompressor 104d, an evaporator 105d, and an evaporation pressure regulating valve 108d are connected in series from the branch point 115 toward a junction 112 via a refrigerant pipe 106. A refrigerant flow FL4 flowing through such a flow path and a refrigerant flow FL flowing through a compressor 102 and a condenser 103 form the fourth refrigeration cycle.

The fourth refrigeration cycle can be controlled similarly to the third refrigeration cycle by setting an evaporation pressure of the evaporator 105d to be higher than the evaporation pressure of an evaporator 105a and lower than the evaporation pressure of an evaporator 105b.

By increasing a control response speed of the device sequentially from an upstream side and in descending order of a flow rate of a refrigerant, hunting is suppressed, and a flow of the refrigerant is stabilized, so that a temperature of a cooling target in the second refrigeration cycle can be precisely adjusted so as to remain within a range of, for example, ±0.1° C. of the set temperature.

### Fourth Embodiment

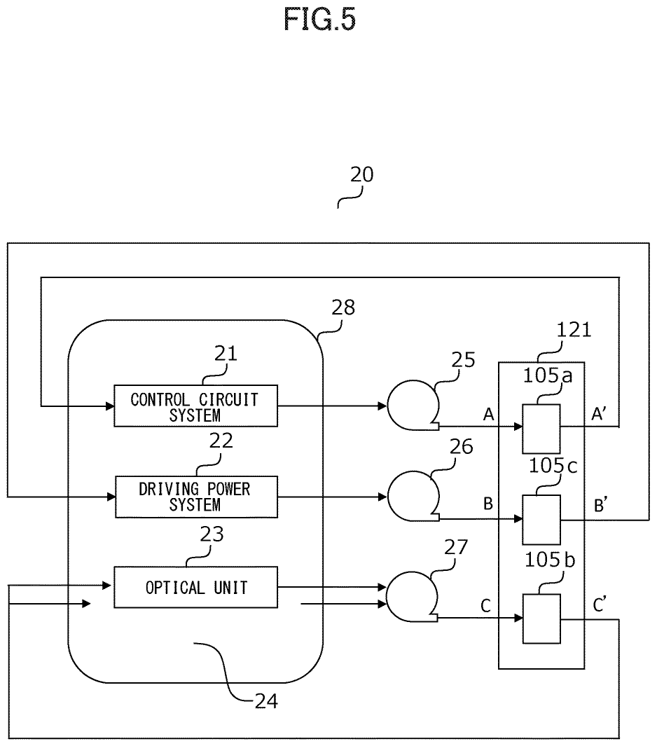

A fourth embodiment in which the cooling device 121 according to the second embodiment is incorporated in industrial equipment to cool each portion of the industrial equipment will be described with reference to FIG. 5. FIG. 5 is a schematic block diagram illustrating an example in which the cooling device 121 according to the second embodiment is incorporated in an exposure device 20 that exposes a fine pattern for semiconductor manufacturing onto a semiconductor substrate.

In a chamber 28 of the exposure device 20, a control circuit system 21, a driving power system 22, an optical unit 23, and the like are disposed. The control circuit system 21 includes, for example, a power supply and a computer, the driving power system 22 includes, for example, a stage driving motor, and the optical unit 23 includes, for example, a light source and a lens driving motor. That is, such units are heat sources, and in the exposure device 20 requiring precise machine accuracy, temperature management not only for the respective units but also for an atmosphere 24 in the chamber is important.

Among the units, the control circuit system 21 and the driving power system 22 have relatively small heat generation amounts and small time variations of the heat generation amount, and thus, are cooled at a substantially constant cooling capacity using an evaporator 105a and an evaporator 105c of the cooling device 121. Specifically, a liquid-cooling mechanism is provided in the control circuit system 21 and the driving power system 22, and a coolant is circulated using a pump 25 and a pump 26.

On the other hand, a heat generation amount around the optical unit 23 is relatively large, and heat diffuses into the atmosphere in the chamber. When a temperature fluctuation occurs in the optical unit 23, an influence on an exposure accuracy of the fine pattern is large. Therefore, it is necessary to sufficiently increase the cooling capacity for the optical unit 23 and the atmosphere in the chamber, and to perform precise control capable of suppressing the temperature fluctuation. Therefore, in the present embodiment, a mechanism for air-cooling the optical unit 23 and the inside of the chamber is provided, and air in the vicinity of the optical unit 23 and the atmosphere in the chamber are sent to an evaporator 105b having a higher cooling capacity, cooled, and circulated using a blower 27.

An operation of the cooling device 121 in the example of FIG. 5 will be described again with reference to FIG. 3.

First, in order to stably operate a compressor 102, it is necessary to suck a refrigerant having a temperature of 35° C. or lower and a pressure of 0.2 MPa or higher and 1.2 MPa or lower. As described below, a refrigerant flow FL2 returning from the evaporator 105b to a junction 112 has a temperature of about 24° C. and a pressure of 1.0 MPa, which causes no problem. The refrigerant sucked into the compressor 102 is compressed until the pressure reaches 2.25 MPa, and sent to a condenser 103 as gas having a temperature of about 65° C.

The refrigerant that has entered the condenser 103 exchanges heat with a cooling liquid flowing between F and F′ to be cooled, and is sent to a branch point 115 as a liquid having a pressure of 2.25 MPa and a temperature of 25° C.

In a decompressor 104b, as described above, an opening/closing degree of an expansion valve is controlled by a control unit 200. A state of the refrigerant flowing out of the decompressor 104b toward the evaporator 105b changes depending on the opening/closing degree of the expansion valve and becomes a gas-liquid two-phase (mixed) state in which liquid and gas coexist, in which the pressure is approximately 1.0 MPa and the temperature is approximately 14° C.

The evaporator 105a exerts a cooling capacity of 2000 W to cool the coolant in the control circuit system 21 of the exposure device 20 from 25° C. to 21° C. In a decompressor 104a, as described above, the opening/closing degree of the expansion valve is controlled by the control unit 200. The refrigerant is in a gaseous state with a pressure of approximately 0.9 MPa and a temperature of approximately 21° C. at an outlet of the evaporator 105a, and flows into the junction 112.

The evaporator 105c exerts a cooling capacity of 4000 W and cools the coolant of the driving power system 22 of the exposure device 20 from 25° C. to 20° C. In a decompressor 104c, as described above, an opening/closing degree of an expansion valve is controlled by a control unit 200.

Although the refrigerant changes depending on the opening/closing degree of the decompressor 104c, the refrigerant is in a gaseous state with a pressure of approximately 0.95 MPa and a temperature of approximately 22° C. at an outlet of the evaporator 105c, and flows into the junction 112.

The evaporator 105b exerts a cooling capacity of 6000 W at the maximum, and cools the air for cooling the optical unit 23 of the exposure device 20 and the atmosphere (air) in the chamber from about 25° C. to 23° C. A temperature of the air before cooled by the evaporator 105b varies around 25° C. depending on an operation state of the exposure device 20. However, since the temperature of the air after cooled by the evaporator 105b should be controlled to be 23° C., the cooling capacity of the evaporator 105b is not always fixed to a constant 6000 W, but is appropriately adjusted. That is, the control unit 200 controls a rotation speed of the compressor 102 by detecting the temperature of the air that has passed through the evaporator 105b as a cooling target 114 using the temperature detection unit 116, and adjusts an amount of the refrigerant flowing through the evaporator 105b such that the temperature of the air becomes 23° C. The refrigerant that has passed through the evaporator 105b is vaporized at a degree of superheat of 10° C. at an evaporator outlet, so that the refrigerant has a temperature of 24° C. and returns to the junction 112.

The cooling device of the present embodiment in which the refrigeration cycle including the evaporator that requires the highest cooling capacity and requires the temperature control with high accuracy and the refrigeration cycle including the evaporator that requires the relatively low cooling capacity and allows the temperature control with relatively low accuracy are arranged in parallel to perform the above-described control has a high utility value in various types of industrial equipment including an exposure machine, and can be suitably used. The numerical values of the pressure, the temperature, the cooling capacity, and the like described above are merely examples, and it goes without saying that the present embodiment is not limited to this example.

### Fifth Embodiment

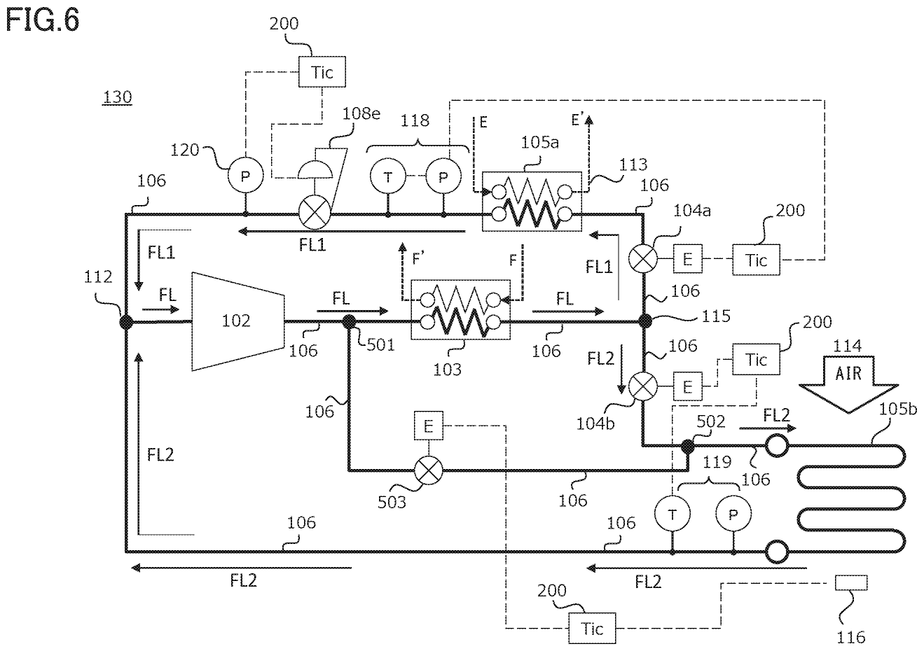

A cooling device according to a fifth embodiment will be described with reference to FIG. 6. A description of matters common to the first embodiment will be simplified or omitted. The fifth embodiment is different from the first embodiment in the following configuration. A branch point 501 is provided between a compressor 102 and a condenser 103, a junction 502 is provided between a decompressor 104b and an evaporator 105b, and the branch point 501 and the junction 502 are connected by a hot gas bypass. A refrigerant pipe 106 of the hot gas bypass is provided with a control valve 503 that can be controlled by a control unit 200 in order to control a flow of hot gas.

While a rotation speed of the compressor 102 is not controlled and is set to a constant value, control is performed to change an opening degree of the control valve 503 provided in a path of the hot gas bypass according to a temperature detected by a temperature detection unit 116. In the first embodiment, a flow rate of a refrigerant flowing into the evaporator 105b is controlled by changing a discharge amount of the compressor 102, but in the present embodiment, the flow rate of the refrigerant flowing into the evaporator 105b is controlled by changing a mixing ratio of a high-temperature and high-pressure refrigerant flowing in via the hot gas bypass. In this case, in order to precisely control a temperature of air as a cooling target 114, if PID control according to Mathematical Formula 1 is applied to the control valve 503 with S1 of Mathematical Formula 1 as the opening degree of the control valve 503, the same effect as that of the first embodiment can be obtained.

The PID control may be applied to a control method different from control using the hot gas bypass as in the present embodiment or control of changing the rotation speed of the compressor as in the first embodiment as long as a cooling capacity of the evaporator 105b can be changed.

An evaporation pressure regulating valve 108a is disposed downstream of the evaporator 105b in the first embodiment, while an evaporation pressure regulating valve 108e is disposed downstream of an evaporator 105a in the present embodiment. This is because a pressure loss occurs at the junction 502 where the refrigerant that has passed through the hot gas bypass and a low-temperature and low-pressure refrigerant in a gas-liquid two-phase state flowing out of the decompressor 104b merge with each other, and a pressure of the refrigerant that has passed through the junction decreases, and thus, a pressure of the refrigerant flowing through FL1 is higher than a pressure of the refrigerant flowing through FL2. Accordingly, the evaporation pressure regulating valve 108e is disposed downstream of the evaporator 105a to reduce the pressure of the refrigerant to a pressure equivalent to the pressure of the refrigerant flowing through FL2. At this time, since the evaporator 105b is controlled within a predetermined range, an approximate value of the pressure of the refrigerant that has passed through the evaporator 105b can be calculated. The value is set as a target value of the evaporation pressure regulating valve 108e, and an opening degree of the evaporation pressure regulating valve 108e is adjusted by a deviation between the target value and a value detected by a pressure detection unit.

In the present embodiment, the control unit 200 can perform the PID control on an opening/closing degree of the control valve 503 and perform the PID control on one or more of an opening/closing degree of the evaporation pressure regulating valve 108e, an opening/closing degree of a decompressor 104a, and an opening/closing degree of the decompressor 104b. In other words, the control unit 200 controls, by the PID control, at least the opening/closing degree of the control valve 503 among the opening/closing degree of the control valve 503, the opening/closing degree of the evaporation pressure regulating valve 108e, the opening/closing degree of the decompressor 104a, and the opening/closing degree of the decompressor 104b.

### Sixth Embodiment

In the first to fifth embodiments, control is performed by substituting a temperature and a pressure detected by detection means into (Mathematical Formula 1) to (Mathematical Formula 4) without processing the temperature and the pressure, but in the present embodiment, before substituting the temperature and the pressure detected by the detection means into (Mathematical Formula 1) to (Mathematical Formula 4), moving average processing is performed on an acquired value. Such processing can cause a difference in control response speed between respective pieces of control equipment.

For example, in the configuration of the first embodiment illustrated in FIG. 1, the degree of superheat calculated to control a decompressor 104a and a decompressor 104b is obtained as follows. A control unit 200 acquires a pressure or a temperature of a refrigerant detected by a detection unit 118 and a detection unit 119 a plurality of times to calculate a moving average, and the control unit 200 calculates the degree of superheat based on the calculated moving average of the pressure or the temperature.

In the present embodiment, the degree of superheat is not calculated based only on a single detection value, but the pressure or the temperature is acquired a plurality of times, and the moving average of the pressure or the temperature is obtained in advance before the degree of superheat is calculated. As a result, a change amount of the pressure or the temperature is reduced, so that a difference can occur between the control response speeds of the decompressor 104a and the decompressor 104b. As a result, an effect of suppressing hunting is increased.

Similarly, in control of an evaporation pressure regulating valve 108a, a temperature of a cooling target 113 cooled by an evaporator 105a is detected a plurality of times by a temperature detection unit 117, and input to the control unit 200 to calculate the moving average, and then the pressure of the refrigerant is calculated based on the calculated moving average of the temperature. As described above, the pressure is not calculated based on only a single detection value, the temperature is acquired a plurality of times, and the moving average of the temperature is obtained in advance before the pressure is calculated. As a result, the change amount of the temperature is reduced, so that a control response speed of the evaporation pressure regulating valve 108a can be set with a margin. As a result, an effect of suppressing hunting is increased.

In a case where time intervals at which detected values are acquired from the respective detection means are equal, the numbers of detection values used to calculate the moving average may be set so as to be prime among the different detection means. As a result, it is possible to suppress coincidence or synchronization of control periods of respective control targets (a compressor 102, the decompressor 104a, the decompressor 104b, and the evaporation pressure regulating valve 108a), and the effect of suppressing hunting further increases.

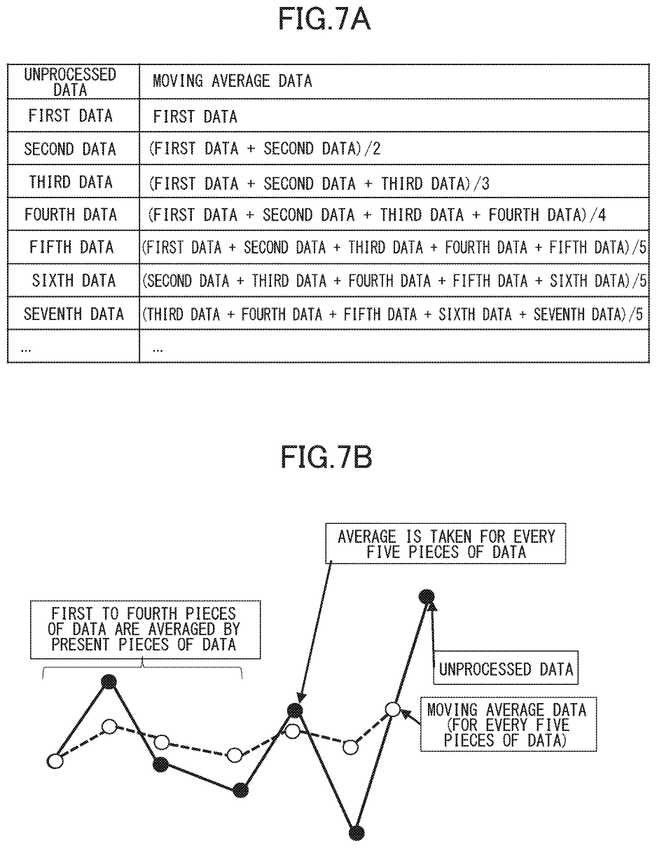

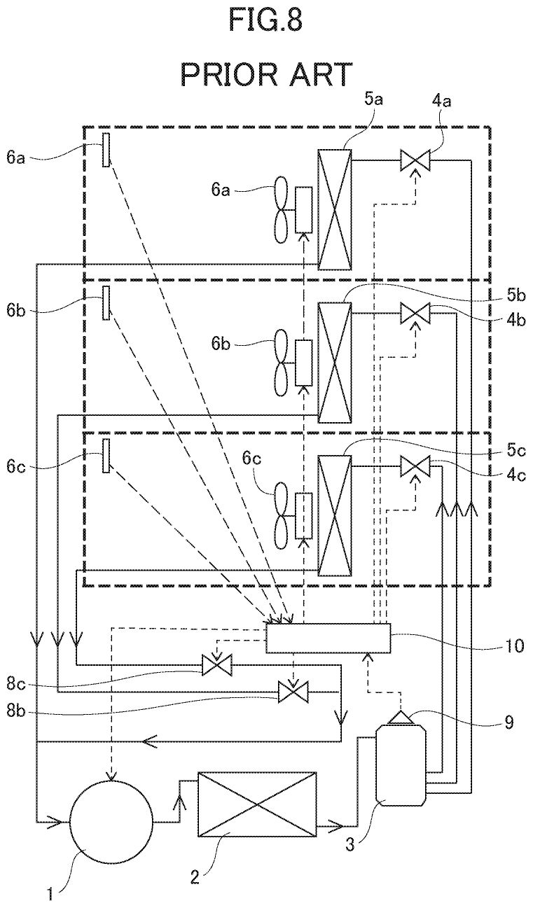

In a case where the moving average processing is performed, when the number of detection values used to calculate the moving average is less than a set number, an average value of all the acquired detection values is substituted, and the moving average processing is performed when the number of detection values becomes equal to or larger than the set value. In a table illustrated in FIG. 7A and a graph illustrated in FIG. 7B, a calculation method in a case where the number of times the moving average processing is to be performed is set to “5” is exemplified.

The number of detection values used to calculate the moving average is set so as to satisfy (Mathematical Formula 6), in which i1 represents the number of times the pressure or the temperature of the refrigerant detected by the detection unit 119 is acquired, i2 represents the number of times the pressure or the temperature of the refrigerant detected by the detection unit 118 is acquired, and i3 represents the number of times the temperature of the cooling target 113 is acquired by the temperature detection unit 117 or the number of times the pressure is acquired by a pressure detection unit 120.

i3>i2>i1>1 Mathematical Formula 6

Here, the moving average processing is not performed on a temperature used to control a rotation speed of the compressor 102. That is, the moving average processing is not performed on a temperature of a cooling target 114 acquired by a temperature detection unit 116, because the control of the compressor 102 needs to be rapidly and precisely performed. With such a setting, a control response speed of the compressor 102 can be higher than any of the control response speed of the decompressor 104b, the control response speed of the decompressor 104a, and the control response speed of the evaporation pressure regulating valve 108a, as in the first to fifth embodiments. The control response speed of the decompressor 104b can be made lower than the control response speed of the compressor 102 and higher than the control response speed of the decompressor 104a and the control response speed of the evaporation pressure regulating valve 108a. The control response speed of the decompressor 104a can be made lower than the control response speed of the compressor 102 and the control response speed of the decompressor 104b, and higher than the control response speed of the evaporation pressure regulating valve 108a. Further, the control response speed of the evaporation pressure regulating valve 108a can be made lower than any of the control response speed of the compressor 102, the control response speed of the decompressor 104b, and the control response speed of the decompressor 104a. At this time, it is sufficient if Kₚ₁, Kₚ₂, Kₚ₃, and Kₚ₄ in (Mathematical Formula 1) to (Mathematical Formula 4) are set such that the order of the control response speeds generated by Mathematical Formula 6 does not change, and it is not necessary to set as in (Mathematical Formula 5).

In the present embodiment, a case where the present disclosure is applied to the configuration of the first embodiment has been described. However, the present disclosure is not limited thereto. Even in a case where the number of refrigeration cycles increases, it is sufficient if a smaller number of measurements for moving average processing is acquired for a value input to the control equipment whose response speed is to be increased

### Modified Embodiment

The technology according to the present disclosure is not limited to the embodiments described above, and many modifications can be made within the technical idea of the present disclosure. For example, all or some of the elements from different embodiments described above may be combined and implemented.

In the first embodiment, the first refrigeration cycle in which the cooling target is, for example, a liquid and the second refrigeration cycle in which the cooling target is, for example, air are provided parallel in such a manner that the compressor and the condenser are shared. The second refrigeration cycle in which the cooling target is, for example, air has the highest cooling capacity and the highest temperature control accuracy. In the second embodiment, the third refrigeration cycle is further provided, and in the third embodiment, the fourth refrigeration cycle is further provided. In each case, the second refrigeration cycle in which the cooling target is, for example, air has the highest cooling capacity and the highest temperature control accuracy.

In carrying out the technology according to the present disclosure, the number of refrigeration cycles provided together is not limited to those in the above example, and more refrigeration cycles may be provided together. Cooling targets of different types or different heat capacities may be cooled in different refrigeration cycles (evaporators) provided together, or cooling targets of the same type or the same heat capacity may be cooled. When a plurality of pieces of equipment are disposed, the control response speed is increased sequentially from the upstream side and in descending order of the flow rate of the refrigerant, so that hunting is prevented, and the flow of the refrigerant is stabilized. As a result, the temperature of the cooling target in the refrigeration cycle having the highest cooling capacity can be precisely adjusted so as to remain within a range of, for example, ±0.1° C. of a set value. An example in which the cooling target in the refrigeration cycle having the highest cooling capacity and the highest temperature control accuracy is air has been described above. However, the cooling target is not necessarily limited to air, and may be another gas or liquid.

The technology according to the present disclosure can also be implemented by processing in which a program for implementing one or more functions of the embodiments is supplied to a system or a device via a network or a storage medium, and one or more processors in a computer of the system or the device read and execute the program. The present disclosure can also be implemented by a circuit (for example, an ASIC) that implements one or more functions.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

What is claimed is:

1. A cooling device comprising:
a first refrigeration cycle including a compressor configured to compress a refrigerant, a condenser configured to cool and condense the refrigerant compressed by the compressor, a first decompressor, and a first evaporator, and in which the refrigerant decompressed by the first decompressor flows to the first evaporator to cool a first cooling target;
a second refrigeration cycle including the compressor, the condenser, a second decompressor, a second evaporator, and an evaporation pressure regulating valve, and in which a refrigerant having a flow rate larger than a flow rate of the first decompressor is decompressed by the second decompressor and flows to the second evaporator to cool a second cooling target; and
a control unit,
wherein
the first refrigeration cycle includes a common flow path in which the compressor and the condenser are connected sequentially and a first flow path in which the first decompressor and the first evaporator are connected sequentially as viewed in a refrigerant flow direction,
the second refrigeration cycle includes the common flow path and a second flow path in which the second decompressor, the second evaporator, and the evaporation pressure regulating valve are connected sequentially as viewed in a refrigerant flow direction,
the common flow path branches into the first flow path and the second flow path at a branch point positioned downstream of the condenser,
the first flow path positioned downstream of the first evaporator and the second flow path positioned downstream of the evaporation pressure regulating valve merge at a junction and are connected to the common flow path positioned upstream of the compressor, and
the control unit is configured to:
control driving of the compressor based on a temperature of the second cooling target cooled by the second evaporator,
acquire a first degree of superheat, which is a degree of superheat of the refrigerant, from a temperature and/or a pressure of the refrigerant at a position downstream of the first evaporator in the first flow path, and control an opening/closing degree of the first decompressor based on the first degree of superheat,
acquire a second degree of superheat, which is a degree of superheat of the refrigerant, from a temperature and/or a pressure of the refrigerant at a position downstream of the second evaporator in the second flow path, and control an opening/closing degree of the second decompressor based on the second degree of superheat, and
control an opening/closing degree of the evaporation pressure regulating valve based on a target pressure of the refrigerant at a position downstream of the evaporation pressure regulating valve or a temperature of the first cooling target cooled by the first evaporator.

2. The cooling device according to claim 1, wherein
the control unit is configured to perform control of the driving of the compressor, control of the opening/closing degree of the first decompressor, control of the opening/closing degree of the second decompressor, and control of the opening/closing degree of the evaporation pressure regulating valve by proportional-integral-differential (PID) control.

3. The cooling device according to claim 2, wherein
a relationship of Kₚ₁>Kₚ₂>Kₚ₃>Kₚ₄ is satisfied, in which
Kₚ₁ represents a constant of proportional control in the PID control of the compressor, Kₚ₂ represents a constant of proportional control in the PID control of the opening/closing degree of the second decompressor, Kₚ₃ represents a constant of proportional control in the PID control of the opening/closing degree of the first decompressor, and Kₚ₄ represents a constant of proportional control in the PID control of the opening/closing degree of the evaporation pressure regulating valve.

4. The cooling device according to claim 2, wherein
a relationship of RS1>RS2>RS3>RS4 is satisfied, in which
RS1 represents a control response speed of the compressor, RS2 represents a control response speed of the second decompressor, RS3 represents a control response speed of the first decompressor, and RS4 represents a control response speed of the evaporation pressure regulating valve.

5. The cooling device according to claim 1, wherein
the first refrigeration cycle includes:
a first detection portion provided between the first evaporator and the junction and configured to detect the temperature and/or the pressure of the refrigerant, and
a first temperature detection unit configured to detect the temperature of the first cooling target cooled by the first evaporator, and
the second refrigeration cycle includes:
a second detection portion provided between the second evaporator and the evaporation pressure regulating valve and configured to detect the temperature and/or the pressure of the refrigerant,
a third detection portion provided between the evaporation pressure regulating valve and the junction and configured to detect the pressure of the refrigerant, and
a second temperature detection unit configured to detect the temperature of the second cooling target cooled by the second evaporator.

6. The cooling device according to claim 5, wherein the control unit is configured to:
control the driving of the compressor by using a detection result of the second temperature detection unit,
control the opening/closing degree of the first decompressor by using a detection result of the first detection portion,
control the opening/closing degree of the second decompressor by using a detection result of the second detection portion, and
control the opening/closing degree of the evaporation pressure regulating valve by using a detection result of the third detection portion or the first temperature detection unit.

7. The cooling device according to claim 5, wherein the control unit is configured to:
control the driving of the compressor by using a detection result of the second temperature detection unit,
control the opening/closing degree of the first decompressor by using a moving average of a detection result of the first detection portion,
control the opening/closing degree of the second decompressor by using a moving average of a detection result of the second detection portion, and
control the opening/closing degree of the evaporation pressure regulating valve by using a moving average of a detection result of the third detection portion or the first temperature detection unit.

8. The cooling device according to claim 7, wherein
a relationship of i3>i2>i1>1 is satisfied, in which
i1 represents a number of detection values used in a case where the moving average of the detection result of the second detection portion is obtained, i2 represents a number of detection values used in a case where the moving average of the detection result of the first detection portion is obtained, and i3 represents a number of detection values used in a case where the moving average of the detection result of the third detection portion or the first temperature detection unit is obtained.

9. The cooling device according to claim 8, wherein
i1, i2, and i3 are prime to each other.

10. The cooling device according to claim 1, further comprising
a third refrigeration cycle including the compressor, the condenser, a third decompressor, a third evaporator, and a second evaporation pressure regulating valve, and in which a refrigerant having a flow rate smaller than a flow rate of the second decompressor is decompressed by the third decompressor and flows to the third evaporator to cool a third cooling target,
wherein an opening/closing degree of the third decompressor is set such that an evaporation pressure of the third evaporator is higher than an evaporation pressure of the first evaporator and lower than an evaporation pressure of the second evaporator.

11. A cooling device comprising:
a first refrigeration cycle including a compressor configured to compress a refrigerant, a condenser configured to cool and condense the refrigerant compressed by the compressor, a first decompressor, a first evaporator, and an evaporation pressure regulating valve, and in which the refrigerant decompressed by the first decompressor flows to the first evaporator to cool a first cooling target;
a second refrigeration cycle including the compressor, the condenser, a second decompressor, and a second evaporator, and in which a refrigerant having a flow rate larger than a flow rate of the first evaporator flows to the second evaporator to cool a second cooling target; and
a control unit,
wherein
the first refrigeration cycle includes a common flow path in which the compressor and the condenser are connected sequentially and a first flow path in which the first decompressor, the first evaporator, and the evaporation pressure regulating valve are connected sequentially as viewed in a refrigerant flow direction,
the second refrigeration cycle includes the common flow path, a second flow path in which the second decompressor and the second evaporator are connected sequentially, and a hot gas bypass that branches from the common flow path between the compressor and the condenser and is connected to the second flow path between the second decompressor and the second evaporator via a control valve as viewed in a refrigerant flow direction,
the common flow path branches into the first flow path and the second flow path at a branch point positioned downstream of the condenser,
the first flow path positioned downstream of the evaporation pressure regulating valve and the second flow path positioned downstream of the second evaporator merge at a junction and are connected to the common flow path positioned upstream of the compressor, and
the control unit is configured to:
control an opening/closing degree of the control valve of the hot gas bypass based on a temperature of the second cooling target cooled by the second evaporator,
acquire a first degree of superheat, which is a degree of superheat of the refrigerant, from a temperature and/or a pressure of the refrigerant at a position downstream of the first evaporator in the first flow path, and control an opening/closing degree of the first decompressor based on the first degree of superheat,
acquire a second degree of superheat, which is a degree of superheat of the refrigerant, from a temperature and/or a pressure of the refrigerant at a position downstream of the second evaporator in the second flow path, and control an opening/closing degree of the second decompressor based on the second degree of superheat, and
control an opening/closing degree of the evaporation pressure regulating valve based on a target pressure of the refrigerant at a position downstream of the evaporation pressure regulating valve.

12. The cooling device according to claim 11, wherein
the control unit is configured to perform at least control of the opening/closing degree of the control valve by PID control among the control of the opening/closing degree of the control valve, the control of the opening/closing degree of the first decompressor, the control of the opening/closing degree of the second decompressor, and the control of the opening/closing degree of the evaporation pressure regulating valve.

13. An exposure device comprising:
the cooling device according to claim 1; and a light source.

14. Industrial equipment comprising:
the cooling device according to claim 1; and a plurality of heat generation elements having different heat generation amounts.

15. An exposure device comprising:
the cooling device according to claim 11; and a light source.

16. Industrial equipment comprising:
the cooling device according to claim 11; and a plurality of heat generation elements having different heat generation amounts.
